(19) United States
(12) Patent Application Publication
(10) Pub. No.: US 2026/0202493 A1
(43) Pub. Date: Jul. 16, 2026

(54) DIAMOND QUANTUM SENSOR

(71) Applicant: TOYOTA JIDOSHA KABUSHIKI KAISHA, Toyota-shi (JP)

(72) Inventor: Hayate Yamano, Susono-shi (JP)

(73) Assignee: TOYOTA JIDOSHA KABUSHIKI KAISHA, Toyota-shi (JP)

(21) Appl. No.: 19/383,705

(22) Filed: Nov. 9, 2025

(30) Foreign Application Priority Data
Nov. 12, 2024 (JP) 2024-197088

(51) Int. Cl. G01R 33/12

(52) U.S. Cl. CPC G01R 33/1284

(57) ABSTRACT

The diamond quantum sensor according to the present disclosure performs simultaneous irradiation of two kinds of microwaves having different frequencies to sense a magnetic field, and when a frequency difference between the two kinds of microwaves is Δf, Δf is in any of ranges of 0.2 MHz≤Δf≤3.0 MHz and 3.8 MHz≤Δf≤5.4 MHz. Δf may be in any of ranges of 0.2 MHz≤Δf≤0.8 MHz, 1.8 MHz≤Δf≤2.8 MHz, and 4.0 MHz≤Δf≤4.8 MHz.

### CROSS-REFERENCE TO RELATED APPLICATION

This application claims priority to Japanese Patent Application No. 2024-197088 filed on Nov. 12, 2024. The disclosure of the above-identified application, including the specification, drawings, and claims, is incorporated by reference herein in its entirety.

### BACKGROUND

### 1. Technical Field

The present disclosure relates to a diamond quantum sensor.

### 2. Description of Related Art

Japanese U.S. Pat. No. 6,616,342 (JP 6616342 B) discloses a magnetic field detection device that is configured of diamonds having a nitrogen vacancy (NV) center and that causes an electron spin at the NV center to interact with a magnetic field to be measured. In the magnetic field detection device of JP 6616342 B, a microwave having a resonance frequency of the NV center at four directions is irradiated onto a detection element.

### SUMMARY

In order to improve magnetic field sensitivity of the detection element, increasing an inclination of a spectrum of the NV center in one direction is required. Therefore, a measure of increasing the power of the microwave is known, but there is a problem in specifications of a generation source of the microwave or power consumption.

The present disclosure has been made to solve such problems, and an object of the present disclosure is to provide a diamond quantum sensor capable of improving sensitivity.

A diamond quantum sensor according to an aspect of the present disclosure performs simultaneous irradiation of two kinds of microwaves having different frequencies to sense a magnetic field. When a frequency difference between the two kinds of microwaves is Δf, Δf is in any of ranges of 0.2 MHz≤Δf≤3.0 MHz and 3.8 MHz≤Δf≤5.4 MHz.

In the diamond quantum sensor, when a frequency difference between the two kinds of microwaves is Δf, Δf may be in any of ranges of 0.2 MHz≤Δf≤0.8 MHz, 1.8 MHz≤Δf≤2.8 MHz, and 4.0 MHz≤Δf≤4.8 MHz.

According to the present disclosure, a diamond quantum sensor capable of improving sensitivity can be provided.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a block diagram illustrating a diamond quantum sensor according to a comparative example;

FIG. 2A is a graph illustrating a photo-detection magnetic resonance spectrum detected by the diamond quantum sensor according to the comparative example, in which the horizontal axis indicates a frequency of a microwave, and the vertical axis indicates a light emission intensity derived from a signal intensity;

FIG. 2B is a graph illustrating a relationship between a power of the microwave and an inclination improvement ratio in the diamond quantum sensor according to the comparative example, in which the horizontal axis indicates the power of the microwave and the vertical axis indicates the inclination improvement ratio;

FIG. 3 is a block diagram illustrating a diamond quantum sensor according to Embodiment 1;

FIG. 4 is a graph illustrating the microwave power and a frequency difference of the microwave used for the measurement, the inclination of the measured spectrum, and the inclination improvement ratio in the diamond quantum sensor according to Embodiment 1;

FIG. 5A is a bar graph illustrating the inclination improvement ratios of Comparative Example 1, Comparative Example 2, and Comparative Example 3, in which the horizontal axis indicates Comparative Example 1, Comparative Example 2, and Comparative Example 3, and the vertical axis indicates the inclination improvement ratios of the spectra in Comparative Example 2 and Comparative Example 3 when the inclination of the spectrum in Comparative Example 1 is set to 1;

FIG. 5B is a bar graph illustrating the inclination improvement ratios of the spectra in Comparative Example 1, Comparative Example 2, Example 2, Example 11, and Example 21, in which the horizontal axis indicates Comparative Example 1, Comparative Example 2, Example 2, Example 11, and Example 21, and the vertical axis indicates the inclination improvement ratios of the spectra in Comparative Example 2, Example 2, Example 11, and Example 21 when the inclination of the spectrum in Comparative Example 1 is set to 1; and

FIG. 6 is a graph illustrating an inclination improvement effect in a case where irradiation of two kinds of microwaves having different frequencies is performed in the diamond quantum sensor according to Embodiment 1, in which the horizontal axis indicates a frequency difference Δf between the two kinds of microwaves, and the vertical axis indicates an inclination improvement ratio.

### DETAILED DESCRIPTION OF EMBODIMENTS

Hereinafter, specific configurations of the present embodiment will be described with reference to the drawings. The following description illustrates a preferred embodiment of the present disclosure, and the scope of the present disclosure is not limited to the following embodiment. Moreover, not all of the configurations described in the present embodiment are indispensable as means for solving the problem. In order to clarify the description, the following description and drawings are omitted and simplified as appropriate. In each drawing, the same elements are designated by the same reference numerals, and repeated descriptions thereof are omitted as necessary.

### Overview of Embodiment

The diamond quantum sensor of the present embodiment improves the magnetic field sensitivity by increasing the inclination of the photo-detection magnetic resonance spectrum. Specifically, the diamond quantum sensor of the present embodiment performs simultaneous irradiation of two kinds of microwaves having different frequencies to sense a magnetic field by performing irradiation of the microwaves for causing the photo-detection magnetic resonance phenomenon. In addition, the inclination of the spectrum is further increased by setting the frequency difference between the frequencies to a specific range. As described above, the diamond quantum sensor in the present embodiment can increase the inclination of the spectrum more than in a case of using one kind of the microwave with the same power by using two kinds of the microwaves, and can improve the sensitivity of the magnetic field detection.

Before describing details of the diamond quantum sensor of the present embodiment, a diamond quantum sensor according to a comparative example using one kind of the microwave will be described. Then, the problems found by the inventors in the diamond quantum sensor according to the comparative example will be described. Thereafter, the diamond quantum sensor of the present embodiment will be described in comparison with the comparative example. As a result, the diamond quantum sensor of the present embodiment is more clearly defined.

### Comparative Example

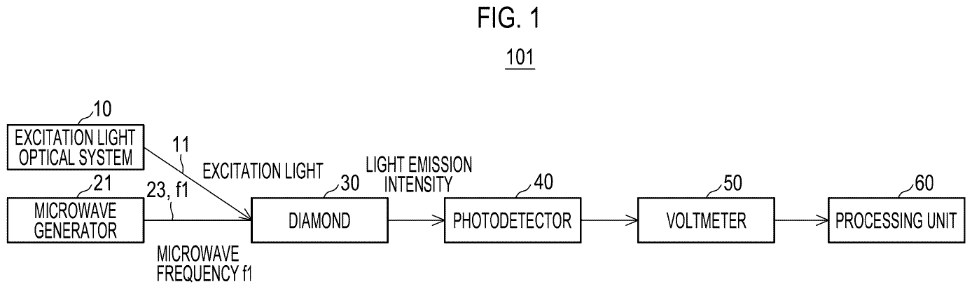

FIG. 1 is a block diagram illustrating a diamond quantum sensor 101 according to a comparative example. As illustrated in FIG. 1, the diamond quantum sensor 101 includes an excitation light optical system 10, a microwave generator 21, a diamond 30, a photodetector 40, a voltmeter 50, and a processing unit 60.

The excitation light optical system 10 irradiates the diamond 30 with the excitation light 11. The excitation light optical system 10 may include a light source that generates the excitation light 11. The excitation light optical system 10 may include an optical member that condenses the excitation light 11 on the diamond 30.

The microwave generator 21 generates the microwaves 23. The microwave generator 21 irradiates the diamond 30 with the generated microwaves 23. The microwave generator 21 generates microwaves 23 having a frequency f1. The microwave generator 21 changes the frequency f1 within a predetermined range.

The diamond 30 has an NV center. For example, the diamond 30 may have the NV center described in Japanese U.S. Pat. No. 6,616,342 (JP 6616342 B). The diamond 30 irradiated with the excitation light 11 emits predetermined light.

The photodetector 40 detects the intensity of the light emitted from the diamond 30. The photodetector 40 outputs the detected light emission intensity to a voltmeter.

The voltmeter 50 converts the light emission intensity into a signal intensity such as a voltage value. The voltmeter 50 outputs the converted signal intensity to the processing unit 60.

The processing unit 60 derives the photo-detection magnetic resonance spectrum from the relationship between the frequency f1 and the signal intensity. The processing unit 60 is, for example, an information processing device, such as a personal computer (PC).

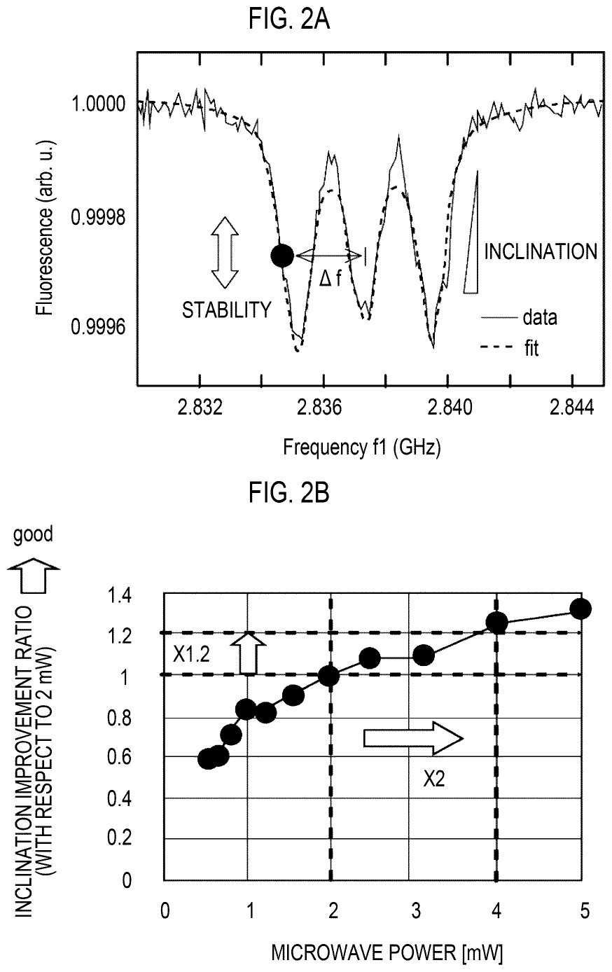

FIG. 2A is a graph illustrating a photo-detection magnetic resonance spectrum detected by the diamond quantum sensor 101 according to the comparative example, in which the horizontal axis indicates the frequency f1 of the microwave 23, and the vertical axis indicates a light emission intensity derived from a signal intensity. The processing unit 60 calculates the magnetic field sensitivity based on the photo-detection magnetic resonance spectrum. Specifically, the magnetic field sensitivity is determined by the inclination of the photo-detection magnetic resonance spectrum and the stability (time variation) of the signal intensity. The inclination of the photo-detection magnetic resonance spectrum is obtained, for example, by differentiating the photo-detection magnetic resonance spectrum with respect to the frequency. The processing unit 60 may regard the maximum value of the inclination as the inclination of the photo-detection magnetic resonance spectrum. The stability of the signal intensity is obtained from the amplitude of the time variation of the signal intensity when the frequency is fixed. The magnetic field sensitivity can be derived from the following Equation (1).

$$Magnetic field sensitivity = stability of signal intensity / inclination of spectrum \qquad ( 1 )$$

Here, since the magnetic field sensitivity is a lower limit value of a detectable magnetic field intensity, it is desirable that the magnetic field sensitivity is small. Therefore, it is desirable to increase the inclination of the spectrum. It has been found that the inclination of the spectrum is increased by increasing the power of the microwave 23 to be emitted to cause the occurrence of the photo-detection magnetic resonance phenomenon.

FIG. 2B is a graph illustrating a relationship between the power of the microwave 23 and the inclination improvement ratio in the diamond quantum sensor 101 according to the comparative example, in which the horizontal axis indicates the power of the microwave 23 and the vertical axis indicates the inclination improvement ratio. Here, the inclination improvement ratio indicates an inclination of a spectrum when the inclination of the spectrum at the predetermined power of the microwave 23 is set to 1.

As illustrated in FIG. 2B, when the power of the microwave 23 is increased, the inclination improvement ratio is also increased. In the diamond quantum sensor 101 of the comparative example, in order to improve the magnetic field sensitivity, a measure is taken to increase the power of the microwaves 23 to be emitted such that the inclination of the spectrum increases.

### Problems Found by Inventors

However, the improvement effect of the power and the inclination of the spectrum of the microwave 23 is not proportional. As the power of the microwave 23 is increased, the improvement effect is weakened. For example, even when the power of the microwave 23 is doubled, the inclination improvement ratio of the spectrum is 1.2 times. That is, there is a limit to the effect of the measure of increasing the power of the microwave 23. Further, there is a certain upper limit on the power of the microwaves 23 that can be emitted from the viewpoint of the specifications of the microwave source and the power consumption requested for the diamond quantum sensor 101. Therefore, there is an upper limit to the inclination of the spectrum, and consequently, the magnetic field sensitivity.

The reason why the improvement effect of the inclination of the spectrum is weakened as the power of the microwave 23 is increased is not clear, but it is considered that there is an upper limit amount of the microwave 23 that can be absorbed by the material (diamond 30). It is not clear whether the amount of the microwaves 23 that can be absorbed by the material can be increased. In addition, the control parameter for controlling the microwave 23 is only two parameters, that is, the power of the microwave 23 and the frequency f1 of the microwave 23. The frequency f1 of the microwave 23 is set to a point where the inclination of the photo-detection magnetic resonance spectrum is maximized. Therefore, the parameter that can be substantially controlled is only the power of the microwave 23, and the above problem occurs.

From the above, the problem is to improve the inclination improvement effect of the spectrum without increasing the irradiation power of the same microwave 23 or increasing the power of the microwave 23 in order to further increase the sensitivity of the diamond quantum sensor 101.

### Embodiment 1

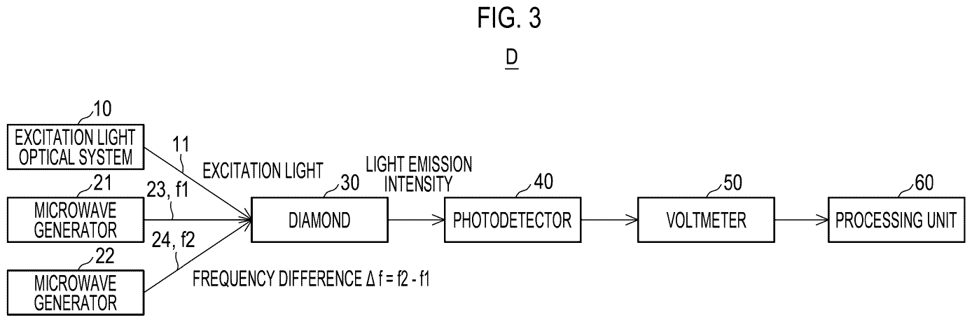

Next, a diamond quantum sensor according to the present embodiment will be described. In order to solve the above-described problems, the diamond quantum sensor of the present embodiment simultaneously irradiates two kinds of microwaves having different frequencies to sense a magnetic field. FIG. 3 is a block diagram illustrating the diamond quantum sensor D according to Embodiment 1. As illustrated in FIG. 3, the diamond quantum sensor D includes an excitation light optical system 10, a microwave generator 21, a microwave generator 22, a diamond 30, a photodetector 40, a voltmeter 50, and a processing unit 60. The diamond quantum sensor D of the present embodiment further includes the microwave generator 22 as compared with the diamond quantum sensor 101 of the comparative example.

The microwave generator 21 generates the microwaves 23. The microwave generator 21 irradiates the diamond 30 with the generated microwaves 23. On the other hand, the microwave generator 22 generates the microwaves 24. The microwave generator 22 irradiates the diamond 30 with the generated microwaves 24. The microwave generator 21 and the microwave generator 22 may be integrated. The integrated microwave generator may generate the microwaves 23 and the microwaves 24.

The microwave generators 21, 22 generate two kinds of microwaves 23, 24 having different frequencies. For example, the microwave generator 21 generates the microwaves 23 having a frequency f1. The microwave generator 22 generates the microwaves 24 having a frequency f2. The microwave generator 21 and the microwave generator 22 simultaneously irradiate the diamond 30 with two kinds of microwaves 23, 24 having different frequencies. A frequency difference between a frequency f1 of the microwaves 23 and a frequency f2 of the microwaves 24 is referred to as Δf. Therefore, the frequency difference Δf is represented by the following Equation (2).

$$Δ f = f 2 - fl \qquad ( 2 )$$

The microwave generators 21, 22 change the frequencies f1, f2 within a predetermined range while maintaining the frequency difference Δf.

The processing unit 60 derives the photo-detection magnetic resonance spectrum from the relationship between the frequencies f1, f2, and the frequency difference Δf and the signal intensity. The processing unit 60 calculates the inclination of the spectrum and the inclination improvement ratio. The inclination of the spectrum may be obtained by differentiating the spectrum with respect to the frequency when any of the frequency f1 or the frequency f2 is taken as the horizontal axis.

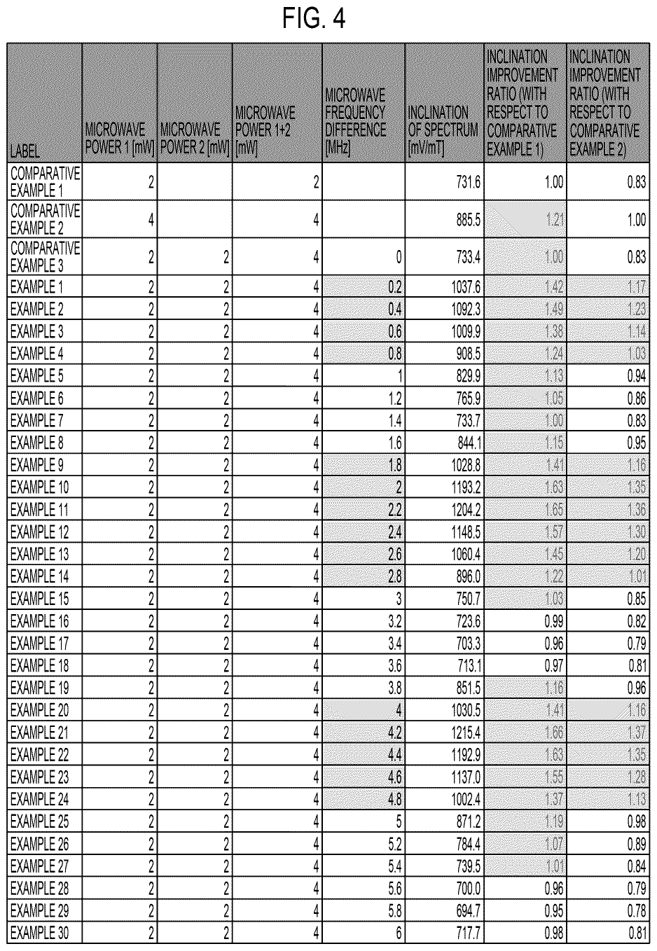

FIG. 4 is a graph illustrating the microwave power and the frequency difference of the microwaves used for the measurement, the inclination of the measured spectrum, and the inclination improvement ratio in the diamond quantum sensor D according to Embodiment 1. FIG. 4 also illustrates the microwave power used for measurement and the inclination and the inclination improvement ratio of the measured spectrum in the diamond quantum sensor 101 of the comparative example. The microwave power 1 indicates the power of the microwave 23, and the microwave power 2 indicates the power of the microwave 24.

As illustrated in FIG. 4, in Examples 1 to 30 using the diamond quantum sensor D, the microwave power 1 and the microwave power 2 used for the measurement are 2 mW. Therefore, in Examples 1 to 30, the total of the microwave power 1 and the microwave power 2 is 4 mW. On the other hand, in Comparative Example 1 using the diamond quantum sensor 101, the microwave power 1 is 2 mW, and in Comparative Example 2, the microwave power 1 is 4 mW. Although Comparative Example 3 is an example using the diamond quantum sensor D, the example is an example in which the frequency difference is 0.

In FIG. 4, an inclination improvement ratio (with respect to Comparative Example 1) indicates the magnitude of the inclination when the inclination of Comparative Example 1 is set to 1. The inclination improvement ratio (with respect to Comparative Example 2) indicates the magnitude of the inclination when the inclination of Comparative Example 2 is set to 1. In a case where the inclination improvement ratio is equal to or greater than 1, an effect is obtained, and the effect is indicated by gray.

As illustrated in FIG. 4, in Examples 1 to 30 of the present embodiment, simultaneous irradiation of two kinds of microwaves 23, 24 having different frequencies is performed. However, in order to improve the inclination improvement ratio, it is not sufficient to perform the simultaneous irradiation of the two kinds of microwaves 23, 24 having different frequencies. Rather, it has been found that the inclination improvement ratio of the spectrum may be decreased (deteriorated). The cause is not clear. It is considered that the microwaves 23, 24 from the two microwave generators 21, 22 interfere with each other in some way and a loss occurs.

In Comparative Example 1, irradiation of one kind of microwave 23 was performed with the same power (2 mW) as each of the microwaves in the microwaves 23, 24. As illustrated in FIG. 4, the principle is not clear, but when the frequency difference Δf between the two kinds of microwaves 23, 24 is set to the following ranges A1, A2, the inclination improvement ratio of the spectrum can be improved as compared with Comparative Example 1.
Range A1: 0.2 Mhz≤Δf≤3.0 Mhz
Range A2: 3.8 Mhz≤Δf≤5.4 Mhz

In addition, in Comparative Example 2, irradiation of one kind of the microwaves 23 was performed with the same power (4 mW) as the power obtained by adding the powers of the microwaves 23, 24. When the frequency difference Δf between the two kinds of microwaves 23, 24 is set to the range B1 to the range B3, the inclination improvement ratio of the spectrum can be improved as compared with Comparative Example 2.
Range B1: 0.2 MHz≤Δf≤0.8 MHz
Range B2: 1.8 MHz≤Δf≤2.8 MHz
Range B3: 4.0 MHz≤Δf≤4.8 MHz

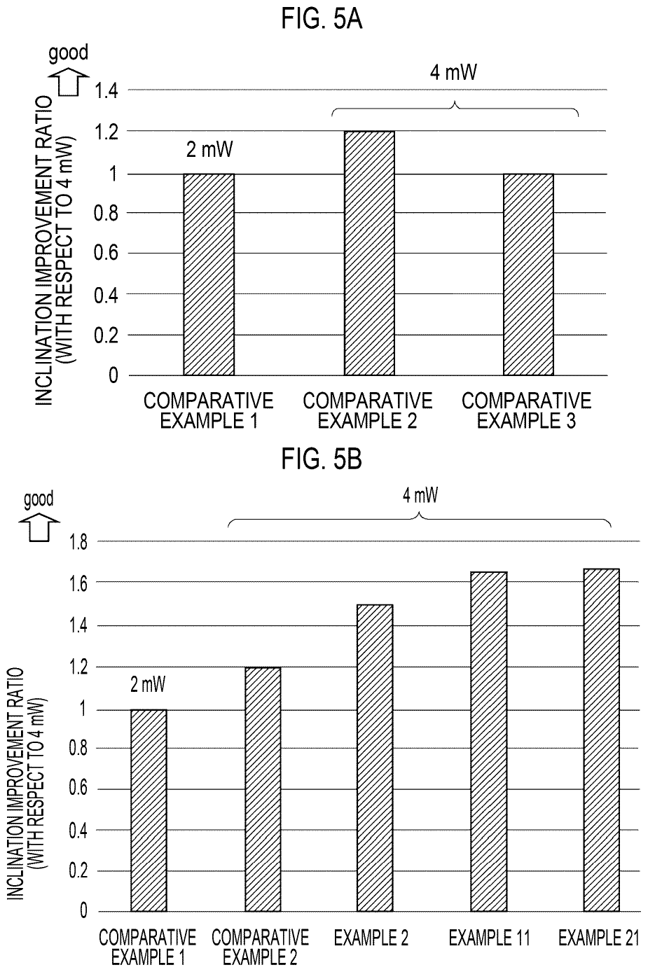

FIG. 5A is a bar graph illustrating the inclination improvement ratio of Comparative Example 1, Comparative Example 2, and Comparative Example 3. The horizontal axis indicates Comparative Example 1, Comparative Example 2, and Comparative Example 3. The vertical axis indicates the inclination of the spectrum in Comparative Example 2 and Comparative Example 3 when the inclination of the spectrum in Comparative Example 1 is set to 1 as an inclination improvement ratio. As illustrated in FIG. 5A, in a case where the power of the microwave 23 is 4 mW in Comparative Example 2, as compared with Comparative Example 1 in which the power of the microwave 23 is 2 mW, the inclination improvement ratio can be 1.2 times. However, in Comparative Example 3 in which the simultaneous irradiation of the two microwaves 23, 24 is performed such that the total power is 4 mW, the inclination improvement ratio cannot be improved. As described above, it is found that merely performing the simultaneous irradiation of the two microwaves 23, 24 is insufficient. The cause is not clear, but it is considered that the microwaves 23, 24 from the two microwave generators 21, 22 interfere with each other in some way, and a loss occurs.

FIG. 5B is a bar graph illustrating the inclination improvement ratio of Comparative Example 1, Comparative Example 2, Example 2, Example 11, and Example 21. The horizontal axis indicates Comparative Example 1, Comparative Example 2, Example 2, Example 11, and Example 21. The vertical axis indicates the inclination improvement ratio of the inclination of the spectrum in Comparative Example 2, Example 2, Example 11, and Example 21 that is obtained by setting the inclination of the spectrum in Comparative Example 1 to 1. As illustrated in FIG. 5B, by setting the frequency difference Δf to any of the ranges A1 and A2 described above or any of the ranges B1 to B3, the inclination improvement effect of the spectrum can be improved as compared with Comparative Example 1 and Comparative Example 2 in which irradiation of one kind of microwave 23 is performed.

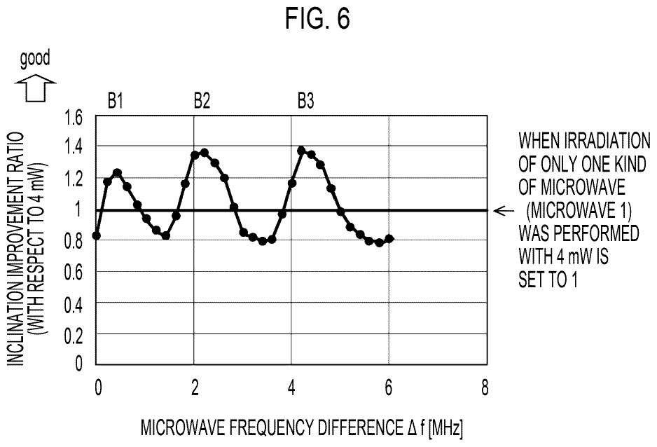

FIG. 6 is a graph illustrating an inclination improvement effect when irradiation of two kinds of microwaves 23, 24 having different frequencies f1, f2 is performed in the diamond quantum sensor D according to Embodiment 1. The horizontal axis indicates a frequency difference Δf between the two kinds of microwaves 23, 24. The vertical axis indicates the inclination improvement ratio. The inclination improvement ratio is a value obtained by setting a value of Comparative Example 2 in which irradiation of only one kind of the microwaves 23 was performed with 4 mW to 1.

As illustrated in FIG. 6, by setting the frequency difference Δf to any of the ranges B1 to B3 described above, the inclination improvement effect of the spectrum can be improved as compared with Comparative Example 2 in which irradiation of one kind of microwave 23 is performed. When the frequency difference Δf is in a range other than the ranges B1 to B3, the inclination improvement ratio of the spectrum is smaller than that in Comparative Example 2. The cause is also not clear, but it is considered that the microwaves 23, 24 from the two microwave generators 21, 22 interfere with each other in some way, and a loss occurs.

According to the present embodiment, by using the two kinds of microwaves 23, 24 having different frequencies, it is possible to increase the inclination of the spectrum more than when one kind of microwave is used at the same power. Therefore, the diamond quantum sensor D capable of improving the sensitivity can be provided.

The present disclosure is not limited to the above-described embodiments, and can be appropriately changed without departing from the spirit of the present disclosure. For example, a combination of the configurations of Embodiment 1 and Comparative Examples 1 to 3 is also included in the technical idea of the embodiment. In addition, the following sensing method using the diamond quantum sensor D is also included in the technical idea of the embodiment.

A sensing method of sensing a magnetic field by performing simultaneous irradiation of two kinds of microwaves having different frequencies is provided. In the sensing method, in a case where a frequency difference between the two kinds of microwaves is Δf, a diamond quantum sensor in any of ranges of 0.2 MHz≤Δf≤3.0 MHz and 3.8 MHz≤Δf≤5.4 MHz is used as Δf.

What is claimed is:

1. A diamond quantum sensor that performs simultaneous irradiation of two kinds of microwaves having different frequencies to sense a magnetic field, wherein when a frequency difference between the two kinds of microwaves is Δf, Δf is in any of ranges of
0.2 MHz≤Δf≤3.0 MHz, and
3.8 MHz≤Δf≤5.4 MHz.

2. The diamond quantum sensor according to claim 1, wherein when a frequency difference between the two kinds of microwaves is Δf, Δf is in any of ranges of
0.2 MHz≤Δf≤0.8 MHz,
1.8 MHz≤Δf≤2.8 MHz, and
4.0 MHz≤Δf≤4.8 MHz.
